(19) United States
(12) Patent Application Publication
(10) Pub. No.: US 2024/0015914 A1
(43) Pub. Date: Jan. 11, 2024

(54) RADIO-FREQUENCY MODULE AND COMMUNICATION DEVICE

(71) Applicant: Murata Manufacturing Co., Ltd., Nagaokakyo-shi (JP)

(72) Inventors: Yoshihiro DAIMON, Nagaokakyo-shi (JP); Takashi YAMADA, Nagaokakyo-shi (JP); Hiromichi KITAJIMA, Nagaokakyo-shi (JP); Kiyoshi AIKAWA, Nagaokakyo-shi (JP); Takanori UEJIMA, Nagaokakyo-shi (JP)

(73) Assignee: Murata Manufacturing Co., Ltd., Nagaokakyo-shi (JP)

(21) Appl. No.: 18/473,336

(22) Filed: Sep. 25, 2023

Related U.S. Application Data
(63) Continuation of application No. PCT/JP2022/010812, filed on Mar. 11, 2022.

(30) Foreign Application Priority Data
Mar. 31, 2021 (JP) 2021-060081

(51) Int. Cl. H05K 7/02; H05K 7/14; H05K 1/18; H05K 1/02; H05K 1/14; H05K 7/20

(52) U.S. Cl. CPC H05K 7/026; H05K 7/1427; H05K 1/181; H05K 1/0237; H05K 1/144; H05K 7/209; H03F 3/245

(57) ABSTRACT

A radio-frequency module includes a module substrate having major surfaces; a module substrate having major surfaces, the major surface being disposed facing the major surface; and plural electronic components disposed between the major surfaces, on the major surface, and on the major surface. The plural electronic components include: a first electronic component including the power amplifier; a second electronic component including a low-noise amplifier; a switch that switches connection and disconnection between a first filter and the power amplifier; and a third electronic component including a PA controller to control the power amplifier or a switch controller to control the switch. The first to third electronic components are separately disposed on the major surface, between the major surfaces, and on the major surface.

### CROSS-REFERENCE TO RELATED APPLICATIONS

This is a continuation application of PCT/JP2022/010812, filed on Mar. 11, 2022, designating the United States of America, which is based on and claims priority to Japanese Patent Application No. JP 2021-060081 filed on Mar. 31, 2021. The entire contents of the above-identified applications, including the specifications, drawings and claims, are incorporated herein by reference in their entirety.

### TECHNICAL FIELD

The present disclosure relates to a radio-frequency module and a communication device.

### BACKGROUND ART

In mobile communication devices, such as cellular phones, radio-frequency front-end modules are becoming more and more complicated with an increasing number of bands to be supported in particular. Patent Document 1 discloses a technique to reduce the size of a radio-frequency module by using two module substrates.

### CITATION LIST

### Patent Document

Patent Document 1: International Publication No. WO 2020/022180

### SUMMARY OF DISCLOSURE

### Technical Problem

According to the aforementioned technique in the related art, however, the reduction in size of the radio-frequency module increases the mounting density of electronic components constituting the radio-frequency module, resulting in poor isolation between the electronic components.

An object of the present disclosure is to provide a radio-frequency module that can be reduced in size and can be inhibited from having poor isolation between electronic components, and to provide a communication device.

### Solution to Problem

A radio-frequency module according to an aspect of the present disclosure includes: a first module substrate including a first major surface and a second major surface that are opposite to each other; a second module substrate including a third major surface and a fourth major surface that are opposite to each other, the third major surface being disposed facing the second major surface; a plurality of electronic components disposed between the second major surface and the third major surface, on the first major surface, and on the fourth major surface; and a plurality of external connection terminals disposed on the fourth major surface. The plurality of electronic components include a first electronic component including a power amplifier, a second electronic component including a low-noise amplifier, a first switch that switches connection and disconnection between a first filter and the power amplifier, and a third electronic component including a PA controller to control the power amplifier or a switch controller to control the first switch. The first electronic component is disposed one of between the second major surface and the third major surface, on the first major surface, and on the fourth major surface. The second electronic component is disposed another one of between the second major surface and the third major surface, on the first major surface, and on the fourth major surface. The third electronic component is disposed other one of between the second major surface and the third major surface, on the first major surface, and on the fourth major surface.

A radio-frequency module according to an aspect of the present disclosure includes: a module substrate including a first major surface and a second major surface that are opposite to each other; a plurality of electronic components disposed on the first major surface, on the second major surface, and within the module substrate; and a plurality of external connection terminals disposed on the second major surface. The plurality of electronic components include a first electronic component including a power amplifier, a second electronic component including a low-noise amplifier, a first switch that switches connection and disconnection between a first filter and the power amplifier, and a third electronic component including a PA controller to control the power amplifier or a switch controller to control the first switch. The first electronic component is disposed one of on the first major surface, on the second major surface, and within the module substrate. The second electronic component is disposed another one of on the first major surface, on the second major surface, and within the module substrate. The third electronic component is disposed other one of on the first major surface, on the second major surface, and within the module substrate.

### Advantageous Effects of Disclosure

The radio-frequency module according to an aspect of the present disclosure can be reduced in size and can be inhibited from having poor isolation between electronic components.

### BRIEF DESCRIPTION OF DRAWINGS

FIG. 1 is a circuit diagram of a radio-frequency circuit and a communication device according to an embodiment.

FIG. 2 is a plan view of a first major surface of a radio-frequency module according to Example 1.

FIG. 3 is a plan view of a second major surface of the radio-frequency module according to Example 1.

FIG. 4 is a plan view of a fourth major surface of the radio-frequency module according to Example 1.

FIG. 5 is a cross-sectional view of the radio-frequency module according to Example 1.

FIG. 6 is a plan view of a first major surface of a radio-frequency module according to Example 2.

FIG. 7 is a plan view of a second major surface of the radio-frequency module according to Example 2.

FIG. 8 is a plan view of a fourth major surface of the radio-frequency module according to Example 2.

FIG. 9 is a cross-sectional view of the radio-frequency module according to Example 2.

FIG. 10 is a plan view of a first major surface of a radio-frequency module according to Example 3.

FIG. 11 is a plan view of a second major surface of the radio-frequency module according to Example 3.

FIG. 12 is a cross-sectional view of the radio-frequency module according to Example 3.

FIG. 13 is another cross-sectional view of the radio-frequency module according to Example 3.

### DESCRIPTION OF EMBODIMENTS

Hereinafter, an embodiment of the present disclosure is described in detail using the drawings. The embodiment described below illustrates a comprehensive or specific example. The numerical values, shapes, materials, constituent components, arrangements and connections of the constituent components, and the like described in the following embodiment are illustrative only and will not limit the present disclosure.

Each drawing is a schematic diagram including proper emphases, omissions, or adjustment of proportions in order to show the present disclosure and is not always illustrated exactly. The shapes, positional relationships, and proportions in each drawing are sometimes different from actual ones. In the drawings, substantially identical configurations are denoted by the same reference numerals, and redundant description may be omitted or simplified.

In each drawing below, x- and y-axes are orthogonal to each other on a plane parallel to the major surfaces of a module substrate. Specifically, when the module substrate is rectangular in a planar view, the x-axis is parallel to a first side of the module substrate, and the y-axis is parallel to a second side of the module substrate that is orthogonal to the first side. z-axis is vertical to the major surfaces of the module substrate, and the positive z-axis direction thereof is an upward direct while the negative z-axis direction is a downward direction.

In the circuit configuration of the present disclosure, “to be coupled” includes either being directly coupled with a connection terminal and/or a trace conductor and also being electrically coupled via another circuit element. “To be coupled between A and B” indicates to be coupled to both A and B between A and B and includes, in addition to be coupled in series to a path connecting A and B, to be coupled in parallel between the path and ground (shunt connection).

In a component arrangement of the present disclosure, a “planar view” refers to a view of an object orthogonally projected onto an x-y plane as seen in the negative z-axis direction. “A overlaps B in a planar view” means that the region of A orthogonally projected onto the x-y plane overlaps the region of B orthogonally projected onto the x-y plane. “A is disposed between B and C” means that at least one of plural line segments connecting any point within B and any point within C passes through A. “A is joined to B” means that A is physically coupled to B. Terms indicating relationships between elements, such as “parallel” or “vertical”, terms indicating element shapes, such as “rectangular”, and numerical ranges express not only their exact meaning but also substantially equivalent ranges, for example, including several percent errors.

In component arrangements of the present disclosure, “a component is disposed in a substrate” includes the component being disposed on a major surface of the substrate and the component being disposed within the substrate. “A component is disposed on a major surface of a substrate” includes either only the component being disposed in contact with a major surface of the substrate or the component being disposed on a major surface side without being in contact with the major surface (for example, the component is stacked atop another component disposed in contact with the major surface). In addition, “a component is disposed on a major surface of a substrate” may include the component being within a recess formed in the major surface. “A component is disposed within a substrate” includes either the component being encapsulated within the module substrate or the component being partially exposed from the substrate although the component being fully disposed between the major surfaces of the substrate and the component being partially disposed within the substrate. “A component is disposed between two major surfaces” includes either the component being disposed in contact with both the two major surfaces or the component being disposed in contact with only one of the two major surfaces or disposed without being in contact with either of the two major surfaces.

### EMBODIMENT

### [1 Circuit Configuration of Radio-Frequency Circuit 1 and Communication Device 5]

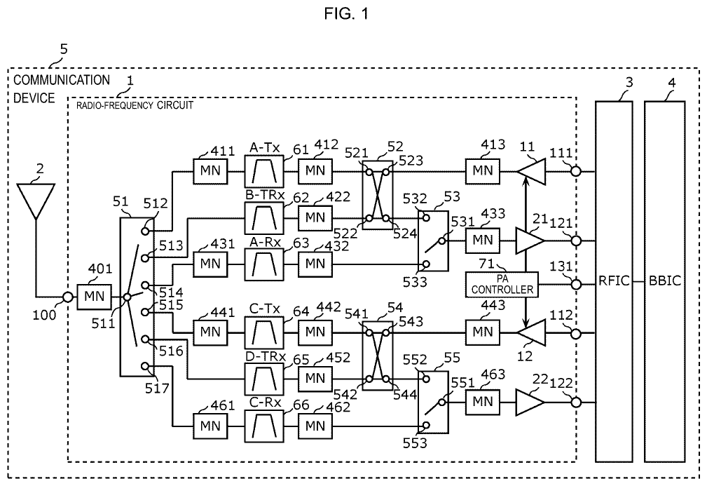

The circuit configurations of a radio-frequency circuit 1 and a communication device 5 according to an embodiment are described with reference to FIG. 1. FIG. 1 is a circuit diagram of the radio-frequency circuit 1 and communication device 5 according to the embodiment.

### [1.1 Circuit Configuration of Communication Device 5]

First, the circuit configuration of the communication device 5 is described. As illustrated in FIG. 1, the communication device 5 according to the embodiment includes the radio-frequency circuit 1, an antenna 2, a radio frequency integrated circuit (RFIC) 3, and a baseband integrated circuit (BBIC) 4.

The radio-frequency circuit 1 transfers radio-frequency signals between the antenna 2 and the RFIC 3. The internal configuration of the radio-frequency circuit 1 is described later.

The antenna 2 is coupled to an antenna connection terminal 100 of the radio-frequency circuit 1. The antenna 2 transmits a radio-frequency signal outputted from the radio-frequency circuit 1. The antenna 2 receives a radio-frequency signal from the outside and outputs the received radio-frequency signal to the radio-frequency circuit 1.

The RFIC 3 is an example of a signal processing circuit to process radio-frequency signals. Specifically, the RFIC 3 performs signal processing, such as down-conversion, for a radio-frequency reception signal inputted through a reception path of the radio-frequency circuit 1 and outputs to the BBIC 4, the reception signal generated through the signal processing. The RFIC 3 performs signal processing, such as up-conversion, for a transmission signal inputted from the BBIC 4 and outputs a radio-frequency transmission signal generated by the signal processing to a transmission path of the radio-frequency circuit 1. The RFIC 3 includes a controller to control switches, amplifiers, and other elements included in the radio-frequency circuit 1. Part of or all of the functions of the RFIC 3 as a controller may be implemented outside the RFIC 3 and, for example, may be implemented in the BBIC 4 or the radio-frequency circuit 1.

The BBIC 4 is a baseband signal processing circuit that performs signal processing using an intermediate frequency band lower than frequencies of radio-frequency signals transferred by the radio-frequency circuit 1. Examples of the signals to be processed by the BBIC 4 are image signals for image display and/or audio signals for voice calls using a speaker.

In the communication device 5 according to the embodiment, the antenna 2 and BBIC 4 are optional constituent elements.

### [1.2 Circuit Configuration of Radio-Frequency Circuit 1]

Next, the circuit configuration of the radio-frequency circuit 1 is described. As illustrated in FIG. 1, the radio-frequency circuit 1 includes power amplifiers (PAs) 11 and 12, low-noise amplifiers (LNAs) 21 and 22, matching networks (MN) 401, 411 to 413, 422, 431 to 433, 441 to 443, 452, and 461 to 463, switches (SWs) 51 to 55, filters 61 to 66, a PA controller (PAC) 71, the antenna connection terminal 100, radio-frequency input terminals 111 and 112, radio-frequency output terminals 121 and 122, and control terminal 131. Hereinafter, the constituent elements of the radio-frequency circuit 1 are described sequentially.

The antenna connection terminal 100 is coupled to the antenna 2 outside the radio-frequency circuit 1.

Each of the radio-frequency input terminals 111 and 112 is a terminal to receive radio-frequency transmission signals from the outside of the radio-frequency circuit 1. In the embodiment, the radio-frequency input terminals 111 and 112 are coupled to the RFIC 3 outside the radio-frequency circuit 1.

Each of the radio-frequency output terminals 121 and 122 is a terminal to supply radio-frequency reception signals to the outside of the radio-frequency circuit 1. In the embodiment, the radio-frequency output terminals 121 and 122 are coupled to the RFIC 3 outside the radio-frequency circuit 1.

The control terminal 131 is terminal to transfer control signals. Specifically, the control terminal 131 is terminal to receive control signals from the outside of the radio-frequency circuit 1 and/or terminals to supply control signals to the outside of the radio-frequency circuit 1.

The control signals are signals concerning control of electronic circuits included in the radio-frequency circuit 1. Specifically, the control signals are digital signals to control at least one of the power amplifiers 11 and 12, low-noise amplifiers 21 and 22, and switches 51 to 55, for example.

The power amplifier 11 is included in a first electronic component. The power amplifier 11 is coupled between the radio-frequency input terminal 111 and the filters 61 and 62 and is able to amplify transmission signals in bands A and B. Specifically, the input end of the power amplifier 11 is coupled to the radio-frequency input terminal 111. The output end of the power amplifier 11 is coupled to the filter 61 via the matching network 413, switch 52, and matching network 412. The output end of the power amplifier 11 is also coupled to the filter 62 via the matching network 413, switch 52, and matching network 422.

The power amplifier 12 is included in a first electronic component. The power amplifier 12 is coupled between the radio-frequency input terminal 112 and the filters 64 and 65 and is able to amplify transmission signals in bands C and D. Specifically, the input end of the power amplifier 12 is coupled to the radio-frequency input terminal 112. The output end of the power amplifier 12 is coupled to the filter 64 via the matching network 443, switch 54, and matching network 442. The output end of the power amplifier 12 is also coupled to the filter 65 via the matching network 443, switch 54, and matching network 452.

The power amplifiers 11 and 12 are electronic components that provide an output signal having a larger energy than an input signal (a transmission signal) based on power supplied from a power supply. Each of the power amplifiers 11 and 12 includes an amplification transistor and may further include an inductor and/or a capacitor. The internal configuration of the power amplifiers 11 and 12 are not limited. For example, each of the power amplifiers 11 and 12 may be a multistage amplifier, a differential amplifier, or a Doherty amplifier.

The low-noise amplifier 21 is included in a second electronic component. The low-noise amplifier 21 is coupled between the filter 62 and 63 and the radio-frequency output terminal 121 and is able to amplify reception signals in the bands A and B. Specifically, the input end of the low-noise amplifier 21 is coupled to the filter 62 via the matching network 433, switches 53 and 52, and matching network 422. The input end of the low-noise amplifier 21 is also coupled to the filter 63 via the matching network 433, switch 53, and matching network 432. The output end of the low-noise amplifier 21 is coupled to the radio-frequency output terminal 121.

The low-noise amplifier 22 is included in the second electronic component. The low-noise amplifier 22 is coupled between the filters 65 and 66 and the radio-frequency output terminal 122 and is able to amplify reception signals in the bands C and D. Specifically, the input end of the low-noise amplifier 22 is coupled to the filter 65 via the matching network 463, switches 55 and 54, and matching network 452. The input end of the low-noise amplifier 22 is also coupled to the filter 66 via the matching network 463, switch 55, and matching network 462. The output end of the low-noise amplifier 22 is coupled to the radio-frequency output terminal 122.

The low-noise amplifiers 21 and 22 are electronic components that provide an output signal having a larger energy than that of an input signal (a reception signal) based on power supplied from the power supply. Each of the low-noise amplifiers 21 and 22 includes an amplification transistor and may further include an inductor and/or a capacitor. The internal configurations of the low-noise amplifiers 21 and 22 are not limited.

Each of the matching networks 401, 411 to 413, 422, 431 to 433, 441 to 443, 452, and 461 to 463 is coupled between two circuit elements and is able to provide impedance matching between the two circuit elements. Thus, each of the matching networks 401, 411 to 413, 422, 431 to 433, 441 to 443, 452, and 461 to 463 is an impedance matching network. Each of the matching networks 401, 411 to 413, 422, 431 to 433, 441 to 443, 452, and 461 to 463 includes an inductor and may further include a capacitor.

The switch 51 is coupled between the antenna connection terminal 100 and the filters 61 to 66. The switch 51 includes terminals 511 to 517. The terminal 511 is coupled to the antenna connection terminal 100. The terminal 512 is coupled to the filter 61 via the matching network 411. The terminal 513 is coupled to the filter 62. The terminal 514 is coupled to the filter 63 via the matching network 431. The terminal 515 is coupled to the filter 64 via the matching network 441. The terminal 516 is coupled to the filter 65. The terminal 517 is coupled to the filter 66 via the matching network 461.

In this connection configuration, the switch 51 is able to connect the terminal 511 to at least one of the terminals 512 to 517 based on a control signal from the RFIC 3, for example. The switch 51 is able to switch whether to couple the antenna connection terminal 100 to each of the filters 61 to 66. The switch 51 is composed of a multi-connection switch circuit, for example, and is sometimes referred to as an antenna switch.

The switch 52 is an example of a first switch. The switch 52 is coupled between the output end of the power amplifier 11 and the filters 61 and 62 and is coupled between the input end of the low-noise amplifier 21 and the filter 62. The switch 52 includes terminals 521 to 524. The terminal 521 is coupled to the filter 61 via the matching network 412. The terminal 522 is coupled to the filter 62 via the matching network 422. The terminal 523 is coupled to the output end of the power amplifier 11 via the matching network 413. The terminal 524 is coupled to the input end of the low-noise amplifier 21 via the switch 53 and matching network 433.

In this connection configuration, the switch 52 is able to couple the terminal 523 to at least one of the terminals 521 and 522 and couple the terminal 522 to at least one of the terminals 523 and 524 based on a control signal from the RFIC 3, for example. The switch 52 is able to switch whether to couple the power amplifier 11 to each of the filters 61 and 62 and is able to switch connections between the filter 62 and the power amplifier 11 and between the filter 62 and the low-noise amplifier 21. The switch 52 is composed of a multi-connection switch circuit, for example.

The switch 53 is coupled between the input end of the low-noise amplifier 21 and the filters 62 and 63. The switch 53 includes terminals 531 to 533. The terminal 531 is coupled to the input end of the low-noise amplifier 21 via the matching network 433. The terminal 532 is coupled to the terminal 524 of the switch 52 and is coupled to the filter 62 via the switch 52 and matching network 422. The terminal 533 is coupled to the filter 63 via the matching network 432.

In this connection configuration, the switch 53 is able to couple the terminal 531 to at least one of the terminals 532 and 533 based on a control signal from the RFIC 3, for example. The switch 53 is thus able to switch whether to couple the low-noise amplifier 21 to each of the filters 62 and 63. The switch 53 is composed of a multi-connection switch circuit, for example.

The switch 54 is an example of a first switch. The switch 54 is coupled between the output end of the power amplifier 12 and the filters 64 and 65 and is coupled between the input end of the low-noise amplifier 22 and the filter 65. The switch 54 includes terminals 541 to 544. The terminal 541 is coupled to the filter 64 via the matching network 442. The terminal 542 is coupled to the filter 65 via the matching network 452. The terminal 543 is coupled to the output end of the power amplifier 12 via the matching network 443. The terminal 544 is coupled to the input end of the low-noise amplifier 22 via the switch 55 and matching network 463.

In this connection configuration, the switch 54 is able to couple the terminal 543 to at least one of the terminals 541 and 542 and couple the terminal 542 to either the terminal 543 or 544 based on a control signal from the RFIC 3, for example. The switch 54 is thus able to switch whether to couple the power amplifier 12 to each of the filters 64 and 65 and switch connections between the filter 65 and the power amplifier 12 and between the filter 65 and the low-noise amplifiers 22. The switch 54 is composed of a multi-connection switch circuit, for example.

The switch 55 is coupled between the input end of the low-noise amplifier 22 and the filters 65 and 66. The switch 55 includes terminals 551 to 553. The terminal 551 is coupled to the input end of the low-noise amplifier 22 via the matching network 463. The terminal 552 is coupled to the terminal 544 of the switch 54 and is coupled to the filter 65 via the switch 54 and matching network 452. The terminal 553 is coupled to the filter 66 via the matching network 462.

In this connection configuration, the switch 55 is able to couple the terminal 551 to at least one of the terminals 552 and 553 based on a control signal from the RFIC 3, for example. The switch 55 is thus able to switch whether to couple the low-noise amplifier 22 to each of the filters 65 and 66. The switch 55 is composed of a multi-connection switch circuit, for example.

The filter 61 (A-Tx) is an example of a first filter. The filter 61 is coupled between the power amplifier 11 and the antenna connection terminal 100. Specifically, an end of the filter 61 is coupled to the antenna connection terminal 100 via the matching network 411, switch 51, and matching network 401. The other end of the filter 61 is coupled to the output end of the power amplifier 11 via the matching network 412, switch 52, and matching network 413. The filter 61 has a pass band including an uplink operation band of the band A for frequency division duplex (FDD) and is able to pass transmission signals in the band A.

The filter 62 (B-TRx) is an example of a first filter. The filter 62 is coupled between the antenna connection terminal 100 and the power amplifier 11 and is coupled between the antenna connection terminal 100 and the low-noise amplifier 21. Specifically, an end of the filter 62 is coupled to the antenna connection terminal 100 via the switch 51 and matching network 401. The other end of the filter 62 is coupled to the output end of the power amplifier 11 via the matching network 422, switch 52, and matching network 413 and is coupled to the input end of the low-noise amplifier 21 via the matching network 422, switches 52 and 53, and matching network 433. The filter 62 has a pass band including the band B for time division duplex (TDD) and is able to pass transmission and reception signals in the band B.

The filter 63 (A-Rx) is coupled between the low-noise amplifier 21 and the antenna connection terminal 100. Specifically, an end of the filter 63 is coupled to the antenna connection terminal 100 via the matching network 431, switch 51, and matching network 401. The other end of the filter 63 is coupled to the input end of the low-noise amplifier 21 via the matching network 432, switch 53, and matching network 433. The filter 63 has a pass band including a downlink operation band of the band A for FDD and is able to pass reception signals in the band A.

The filter 64 (C-Tx) is an example of the first filter. The filter is coupled between the power amplifier 12 and the antenna connection terminal 100. Specifically, an end of the filter 64 is coupled to the antenna connection terminal 100 via the matching network 441, switch 51, and matching network 401. The other end of the filter 64 is coupled to the output end of the power amplifier 12 via the matching network 442, switch 54, and matching network 443. The filter 64 has a pass band including an uplink operation band of the band C for FDD and is able to pass transmission signals in the band C.

The filter 65 (D-TRx) is an example of the first filter. The filter 65 is coupled between the antenna connection terminal 100 and the power amplifier 12 and is coupled between the antenna connection terminal 100 and the low-noise amplifier 22. Specifically, an end of the filter 65 is coupled to the antenna connection terminal 100 via the switch 51 and matching network 401. The other end of the filter 65 is coupled to the output end of the power amplifier 12 via the matching network 452, switch 54, and matching network 443 and is coupled to the input end of the low-noise amplifier 22 via the matching network 452, switches 54 and 55, and matching network 463. The filter 65 has a pass band including the band D for TDD and is able to pass transmission and reception signals in the band D.

The filter 66 (C-Rx) is coupled between the low-noise amplifier 22 and the antenna connection terminal 100. Specifically, an end of the filter 66 is coupled to the antenna connection terminal 100 via the matching network 461, switch 51, and matching network 401. The other end of the filter 66 is coupled to the input end of the low-noise amplifier 22 via the matching network 462, switch 55, and matching network 463. The filter 66 has a pass band including a downlink operation band of the band C for FDD and is able to pass reception signals in the band C.

The PA controller 71 is included in a third electronic component and is able to control the power amplifiers 11 and 12. The PA controller 71 receives digital control signals from the RFIC 3 via the control terminal 131 and outputs control signals to the power amplifiers 11 and 12. The PA controller 71 may further output control signals to the switches 51 to 55 to control the switches 51 to 55. Alternatively, the PA controller 71 may be a switch controller to output control signals only to the switches 51 to 55 among the power amplifiers 11 and 12 and the switches 51 to 55.

The bands A to D are frequency bands for communication systems built by using a radio access technology (RAT). The bands A to D are previously defined by a standards body or the like (the 3rd Generation Partnership Project (3GPP) or the Institute of Electrical and Electronics Engineers (IEEE), for example). Examples of the communication systems are a 5th generation new radio (5GNR) system, a long term evolution (LTE) system, and a wireless local area network (WLAN) system.

The bands A and B may be included in a different band group from the bands C and D or may be included in the same band group. Herein, a band group indicates a range of frequencies including plural bands. Band groups can be an ultra-high band group (3300 to 5000 MHz), a high-band group (2300 to 2690 MHz), a mid-band group (1427 to 2200 MHz), and a low-band group (698 to 960 MHz), for example, but are not limited thereto. For example, the band groups may include a band group including an unlicensed band not lower than 5 GHz or a band group in the millimeter wave band.

For example, the bands A and B may be included in the high-band group while the bands C and D are included in the mid-band group. Alternatively, the bands A and B may be included in the mid- or high-band group while the bands C and D are included in the low-band group.

The radio-frequency circuit 1 is illustrated by way of example in FIG. 1 and is not limited thereto. For example, the bands covered by the radio-frequency circuit 1 are not limited to the bands A to D. For example, the radio-frequency circuit 1 may be configured to cover five bands or more. In this case, the radio-frequency circuit 1 may include filters for bands E, F, G ⋅ ⋅ ⋅ . Alternatively, for example, the radio-frequency circuit 1 may be configured to cover only the bands A and B but not the bands C and D. In this case, the radio-frequency circuit 1 may or may not include the power amplifier 12, low-noise amplifier 22, matching networks 441 to 443, 452, and 461 to 463, radio-frequency input terminal 112, and radio-frequency output terminal 122. Alternatively, for example, the radio-frequency circuit 1 may be a transmit-only circuit. In this case, the radio-frequency circuit 1 may or may not include the low-noise amplifiers 21 and 22, matching networks 431 to 433 and 461 to 463, the switches 53 and 55, the filters 63 and 66, and the radio-frequency output terminals 121 and 122. Alternatively, for example, the radio-frequency circuit 1 may be a receive-only circuit. In this case, the radio-frequency circuit 1 may or may not include the power amplifiers 11 and 12, matching networks 411 to 413 and 441 to 443, switches 52 and 54, filters 61 and 64, and radio-frequency input terminals 111 and 112.

The radio-frequency circuit 1 may or may not include all the matching networks 401, 411 to 413, 422, 431 to 433, 441 to 443, 452, and 461 to 463. Furthermore, the radio-frequency circuit 1 may be coupled to plural antennas and may include plural antenna connection terminals, for example. The radio-frequency circuit 1 may include more radio-frequency input terminals. In this case, a switch that is able to switch connections between the power amplifiers and the plural radio-frequency input terminals may be provided between the power amplifiers and the plural radio-frequency input terminals. The radio-frequency circuit 1 may include more radio-frequency output terminals. In this case, a switch that is able to switch connections between the low-noise amplifiers and the plural radio-frequency output terminals may be provided between the low-noise amplifiers and the plural radio-frequency output terminals.

### [2 Example of Radio-Frequency Circuit 1]

### 2.1 Example 1

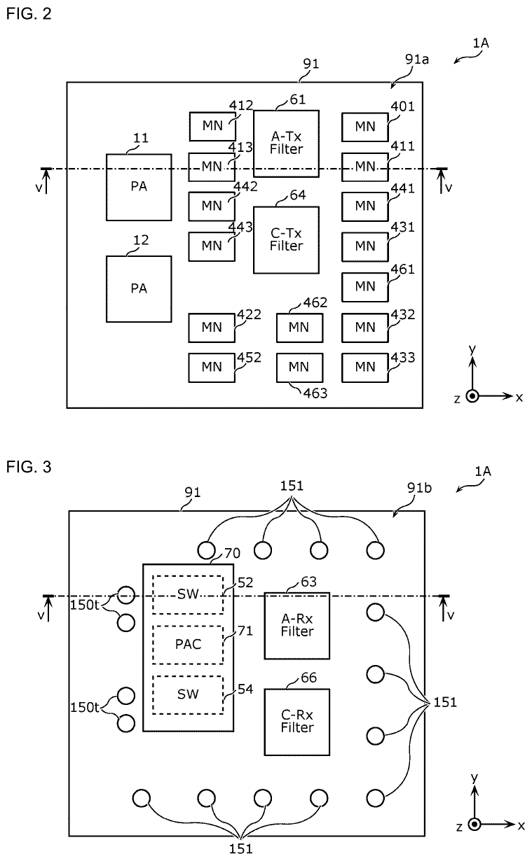

As Example 1 of the radio-frequency circuit 1 according to the embodiment, a radio-frequency module 1A, in which the radio-frequency circuit 1 is implemented, is described with reference to FIGS. 2 to 5.

### [2.1.1 Component Arrangement of Radio-Frequency Module 1A]

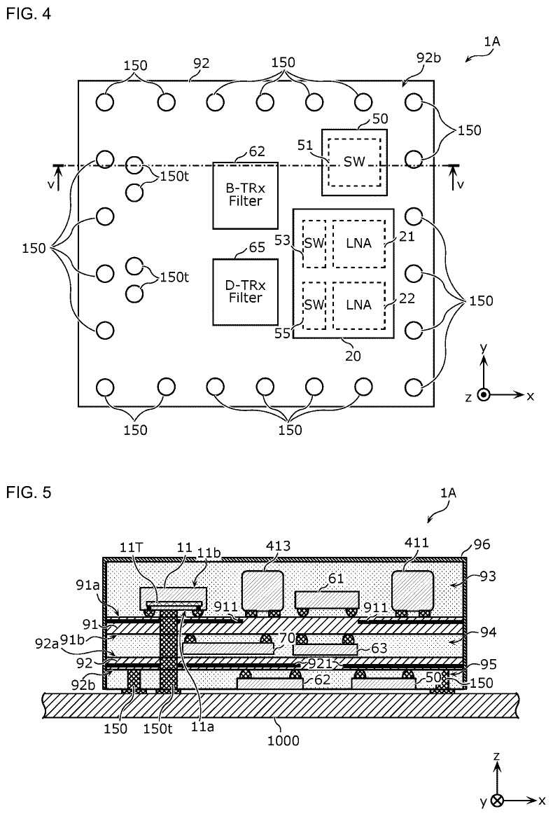

FIG. 2 is a plan view of a major surface 91a of the radio-frequency module 1A according to Example 1. FIG. 3 is a plan view of a major surface 91b of the radio-frequency module 1A according to Example 1. FIG. 3 is a view seen through the major surface 91b side of a module substrate 91 as seen in the positive z-axis direction. FIG. 4 is a plan view of a major surface 92b of the radio-frequency module 1A according to Example 1. FIG. 4 is a view seen through the major surface 92b side of a module substrate 92 as seen in the positive z-axis direction. FIG. 5 is a cross-sectional view of the radio-frequency module 1A according to Example 1. The cross section of the radio-frequency module 1A in FIG. 5 is taken along a line v-v of FIGS. 2 to 4.

FIGS. 2 to 5 do not illustrate traces connecting plural electronic components disposed in the module substrates 91 and 92. FIGS. 2 to 4 do not illustrate resin members 93 to 95 covering plural electronic components and a shield electrode layer 96, which covers the surfaces of the resin members 93 to 95.

In addition to the plural electronic components including the plural circuit elements illustrated in FIG. 1, the radio-frequency module 1A includes the module substrates 91 and 92, the resin members 93 to 95, the shield electrode layer 96, plural external connection terminals 150, plural heat dissipation conductors 150t, and plural inter-substrate connection terminals 151.

The module substrate 91 is an example of a first module substrate and includes the major surfaces 91a and 91b, which are opposite to each other. The major surfaces 91a and 91b are examples of first and second major surfaces, respectively.

The module substrate 92 is an example of a second module substrate and includes the major surfaces 92a and 92b, which are opposite to each other. The major surfaces 92a and 92b are examples of third and fourth major surfaces, respectively.

The module substrates 91 and 92 are disposed so that the major surface 91b of the module substrate 91 faces the major surface 92a of the module substrate 92. The module substrates 91 and 92 are disposed at such a distance that the electronic components can be disposed between the major surfaces 91b and 92a. The plural electronic components are disposed in the two module substrates 91 and 92 and, specifically, are separated into three layers: between the major surfaces 91b and 92a; on the major surface 91a; and on the major surface 92b.

A ground conductor 911 may be formed inside the module substrate 91 in a direction parallel to the major surfaces 91a and 91b. This enhances the isolation between the electronic components disposed on the major surface 91a and the electronic components disposed on the major surface 91b. A ground conductor 921 may also be formed inside the module substrate 92 in a direction parallel to the major surfaces 92a and 92b. This enhances the isolation between the electronic components disposed on the major surface 92a and the electronic components disposed on the major surface 92b.

In FIGS. 2 to 5, the module substrates 91 and 92 have rectangular shapes of the same size in a planar view. The module substrates 91 and 92 may have different sizes and/or different shapes. The shapes of the module substrates 91 and 92 are not limited to rectangles.

Each of the module substrates 91 and 92 can be, but not limited to, a low temperature co-fired ceramic (LTCC) substrate or a high temperature co-fired ceramic (HTCC) substrate, which includes a laminate structure of plural dielectric layers, an embedded printed circuit board, a substrate including a redistribution layer (RDL), a printed circuit board, or the like, for example.

On the major surface 91a (the upper layer), the power amplifiers 11 and 12, matching networks 401, 411 to 413, 422, 431 to 433, 441 to 443, 452, and 461 to 463, and the filters 61 and 64 are disposed.

Each of the power amplifiers 11 and 12 includes an amplification transistor and is included in a first electronic component. The amplification transistor of the power amplifier 11 is formed in a circuit section 11T. As illustrated in FIG. 5, the circuit section 11T is formed at a position near the major surface 11a of the major surfaces 11a (fifth major surface) and 11b (sixth major surface) of the power amplifier 11, which are opposite to each other. The power amplifier 11 has the major surface 11a disposed facing the major surface 91a. Similarly, the amplification transistor of the power amplifier 12 is formed in a circuit section 12T. Although not illustrated, the circuit section 12T is formed at a position near the major surface 12a of the major surfaces 12a (fifth major surface) and 12b (sixth major surface) of the power amplifier 12, which are opposite to each other. The power amplifier 12 has the major surface 12a disposed facing the major surface 91a.

The power amplifiers 11 and 12 are composed of complementary metal oxide semiconductors (CMOSs), for example, and specifically, can be manufactured by a silicon-on-insulator (SOI) process. The power amplifiers 11 and 12 can be thereby manufactured at low cost. The power amplifiers 11 and 12 may be composed of at least one of gallium arsenide (GaAs), silicon germanium (SiGe), and gallium nitride (GaN). This can implement the power amplifiers 11 and 12 of high quality. The semiconductor materials of the power amplifiers 11 and 12 are not limited to the aforementioned materials.

Each of the matching networks 401, 411 to 413, 422, 431 to 433, 441 to 443, 452, and 461 to 463 is, for example, composed of a chip inductor. The chip inductors are surface mount devices (SMDs) each constituting an inductor. The chip inductors are disposed on the major surface 91a. The chip inductors are not disposed either between the major surfaces 91b and 92a or on the major surface 92b. The chip inductors are thus disposed only in the upper layer of the three layers.

Each matching network may include a chip inductor and/or a chip capacitor, and the positions of the chip capacitors are not limited. All the matching networks are not necessarily surface-mounted. For example, an inductor and/or a capacitor included in any matching network may be formed within the module substrate 91 and/or 92.

The filters 61 and 64 may be composed of, but not limited to, any one of a surface acoustic wave (SAW) filter, a bulk acoustic wave (BAW) filter, an LC resonance filter, and a dielectric filter, for example.

The resin member 93 covers the major surface 91a and the electronic components on the major surface 91a. The resin member 93 has a function of enhancing the reliability, including mechanical strength and moisture resistance, of the electronic components on the major surface 91a. The resin member 93 may or may not be included in the radio-frequency module 1A.

Between the major surfaces 91b and 92a (the middle layer), an integrated circuit 70, filters 63 and 66, the plural heat dissipation conductors 150t, and the plural inter-substrate connection terminals 151 are disposed. Between the major surfaces 91b and 92a, the resin member 94 is injected and covers the electronic components disposed between the major surfaces 91b and 92a.

The integrated circuit 70 is an example of a third electronic component including transistors and includes at least one of a PA controller and a switch controller. The integrated circuit 70 includes switches 52 (first switch) and 54 (first switch) and the PA controller 71. The transistors constituting the switches 52 and 54 and PA controller 71 are formed in a circuit section of the integrated circuit 70. The circuit section can be, for example, the major surface of the integrated circuit 70 facing the module substrate 91. The integrated circuit 70 is disposed on the major surface 91b. The integrated circuit 70 may or may not include the switches 52 and 54.

The integrated circuit 70 is composed of a CMOS, for example, and specifically, may be manufactured by a SOI process. The integrated circuit 70 may be composed of at least one of GaAs, SiGe, and GaN. The semiconductor material of the integrated circuit 70 is not limited to the aforementioned materials.

The filters 63 and 66 may be composed of, but not limited to, any one of a SAW filter, a BAW filter, an LC resonance filter, or a dielectric filter, for example.

The plural electronic components (the integrated circuit 70 and the filters 63 and 66) disposed between the major surfaces 91b and 92a are electrically coupled to the module substrate 91 with electrodes interposed therebetween. The electrodes of each electronic component are provided on the side facing the module substrate 91.

The plural heat dissipation conductors 150t overlap the power amplifiers 11 and 12 in a planar view and serve as heat dissipation electrodes of the power amplifiers 11 and 12. More specifically, as illustrated in FIGS. 4 and 5, the plural heat dissipation conductors 150t each have one end joined to the major surface 11a of the power amplifier 11 or the major surface 12a of the power amplifier 12, and extend along a direction (negative z-axis direction) from the major surface 91a to the major surface 92b. The plural heat dissipation conductors 150t each have the other end joined to the motherboard 1000 by at least one of a metal electrode and solder. This can increase the heat dissipation of the power amplifiers 11 and 12. The heat dissipation conductors 150t are composed of, for example, a via conductor having a circular or elliptical cross section parallel to the module substrate 91 and a copper post electrode. However, the shape and material of the heat dissipation conductors 150t are not limited thereto.

In a planar view of the module substrate 91, the power amplifiers 11 and 12 and the integrated circuit 70 at least partially overlap each other. This can shorten control traces connecting the power amplifiers 11 and 12 to the PA controller 71.

The plural inter-substrate connection terminals 151 are electrodes to electrically couple the module substrates 91 and 92. The inter-substrate connection terminals 151 are composed of copper post electrodes, for example. The shape and material of the inter-substrate connection terminals 151 are not limited thereto.

The resin member 94 covers the major surfaces 91b and 92a and the electronic components between the major surfaces 91b and 92a. The resin member 94 has a function of enhancing the reliability, including mechanical strength and moisture resistance, of the electronic components between the major surfaces 91b and 92a. The resin member 94 may or may not be included in the radio-frequency module 1A.

On the major surface 92b (the lower layer), the filters 62 and 65, the integrated circuits 20 and 50, the plural external connection terminals 150, and the plural heat dissipation conductors 150t are disposed.

The filters 62 and 65 may be composed of, but not limited to, any one of a SAW filter, a BAW filter, an LC resonance filter, or a dielectric filter, for example.

The integrated circuit 20 is an example of a second electronic component including at least transistors. The integrated circuit 20 includes the low-noise amplifiers 21 and 22 and switches 53 and 55. The circuit elements constituting the low-noise amplifiers 21 and 22 and the switches 53 and 55 are formed on the circuit surface of the integrated circuit 20. The circuit surface can be, for example, the major surface of the integrated circuit 20 facing the module substrate 92. The integrated circuit 20 is disposed on the major surface 92b.

The integrated circuit 50 includes a switch 51. The circuit elements constituting the switch 51 are formed on the circuit surface of a switch device. The circuit surface can be, for example, the major surface of the switch device facing the module substrate 92. The switch 51 may be included in the integrated circuit 20 or 70.

The integrated circuits 20 and 50 is composed of a CMOS, for example, and specifically, may be manufactured by a SOI process. The integrated circuits 20 and 50 may be composed of at least one of GaAs, SiGe, and GaN. The semiconductor material of the integrated circuits 20 and 50 is not limited to the aforementioned materials.

The plural external connection terminals 150 include the antenna connection terminal 100, radio-frequency input terminals 111 and 112, radio-frequency output terminals 121 and 122, and control terminal 131, which are illustrated in FIG. 1, and further include ground terminals. The plural external connection terminals 150 are individually joined to input-output terminals, a ground terminal, and/or other terminals on a motherboard 1000, which is laid in the negative z-axis direction with respect to the radio-frequency module 1A. The plural external connection terminals 150 can be copper post electrodes, for example. However, the shape and material of the external connection terminals 150 are not limited thereto.

The resin member 95 covers the major surface 92b and the electronic components on the major surface 92b. The resin member 95 has a function of enhancing the reliability, including mechanical strength and moisture resistance, of the electronic components on the major surface 92b. The resin member 95 may or may not be included in the radio-frequency module 1A.

The shield electrode layer 96 is a metallic thin film formed by sputtering, for example. The shield electrode layer 96 is formed so as to cover the upper surface of the resin member 93 and lateral faces of the resin members 93 to 95 and module substrates 91 and 92. The shield electrode layer 96 is coupled to the ground and inhibits external noise from entering the electronic components constituting the radio-frequency module 1A. The shield electrode layer 96 does may or may not be included in the radio-frequency module 1A.

As described above, in the radio-frequency module 1A according to Example 1, the power amplifiers 11 and 12 (first electronic component), the integrated circuit 70 (third electronic component), and the low-noise amplifiers 21 and 22 (second electronic component) are separately disposed on the major surface 91a, between the major surfaces 91b and 92a, and on the major surface 92b.

In the radio-frequency module 1A according to Example 1, the first electronic component may be disposed one of (i) on the major surface 91a, (ii) between the major surfaces 91b and 92a, and (iii) on the major surface 92b. The second electronic component may be disposed another one of (i) to (iii) where the first electronic component is not disposed. The third electronic component may be disposed the other one of (i) to (iii) where the first and second electronic components are not disposed.

### [2.1.2 Effect of Radio-Frequency Module 1A]

As described above, the radio-frequency module 1A according to Example 1 includes: the module substrate 91, which includes the major surfaces 91a and 91b opposite to each other; the module substrate 92, which includes the major surfaces 92a and 92b opposite to each other, the major surface 92a being disposed facing the major surface 91b; the plural electronic components disposed between the major surfaces 91b and 92a, on the major surface 91a, and on the major surface 92b; and the plural external connection terminals 150 disposed on the major surface 92b. The plural electronic components include: the first electronic component including the power amplifiers 11 and/or 12; the second electronic component including the low-noise amplifiers 21 and/or 22; the switches 52 and/or 54 that switch connection and disconnection between the first filter and the power amplifiers 11 and/or 12; and the third electronic component including the PA controller to control the power amplifiers 11 and/or 12 or the switch controller to control the switches 52 and/or 54. The first electronic component is disposed one of between the major surfaces 91b and 92a, on the major surface 91a, and on the major surface 92b. The second electronic component is disposed another one of between the major surfaces 91b and 92a, on the major surface 91a, and on the major surface 92b. The third electronic component is disposed the other one of between the major surfaces 91b and 92a, on the major surface 91a, and on the major surface 92b.

According to such a configuration, the plural electronic components are disposed in three layers, including between the major surfaces 91b and 92a, on the major surface 91a, and on the major surface 92b. This can implement reduction in area of the radio-frequency module 1A in a planar view, that is, reduction in size of the radio-frequency module 1A. Since the power amplifiers 11 and/or 12 and the power amplifier controller and/or the switch controller are disposed with the module substrate 91 interposed therebetween, the digital control signal inputted and outputted to and from the power amplifier controller and/or the switch controller, for example, can be inhibited from entering the power amplifiers 11 and/or 12 as digital noise. Since the low-noise amplifiers 21 and/or 22 and the power amplifier controller and/or the switch controller are disposed with the module substrate 92 interposed therebetween, control signals inputted and outputted to and from the power amplifier/switch controller, for example, can be inhibited from entering the low-noise amplifiers 21 and/or 22 as noise. Since the power amplifiers 11 and/or 12 and the low-noise amplifiers 21 and/or 22 are disposed with the module substrates 91 and 92 interposed therebetween, transmission signals and harmonics thereof outputted from the power amplifiers 11 and/or 12, for example, can be inhibited from entering the low-noise amplifiers 21 and/or 22 as noise. Therefore, the radio-frequency module can be reduced in size and can be inhibited from having poor isolation between the electronic components.

In the radio-frequency module 1A according to Example 1, for example, the first electronic component and the third electronic component may at least partially overlap each other in a planar view of the module substrate 91.

According to such a configuration, control traces connecting the power amplifiers 11 and/or 12 to the power amplifier controller and/or switch controller can be shortened, thus reducing noise generated from the control traces.

In the radio-frequency module 1A according to Example 1, for example, the first electronic component may be disposed on the major surface 91a and the third electronic component may be disposed on the major surface 91b.

According to such a configuration, the control traces can be shortened since the power amplifiers 11 and/or 12 and the power amplifier controller and/or switch controller are disposed opposite to each other with the module substrate 91 interposed therebetween.

In the radio-frequency module 1A according to Example 1, for example, the power amplifier 11 includes the major surfaces 11a and 11b opposite to each other, and the circuit section 11T that is formed at a position closer to the major surface 11a than the major surface 11b and includes the amplification transistor. The power amplifier 11 has the major surface 11a disposed facing the major surface 91a. The heat dissipation conductor 150t extending along the direction from the major surface 91a to the major surface 92b is joined to the major surface 11a.

According to such a configuration, the heat dissipation of the power amplifier 11 can be increased.

In the radio-frequency module 1A according to Example 1, for example, the second electronic component may be disposed on the major surface 92b.

A communication device 5 according to Example 1 includes: an RFIC 3 that processes radio-frequency signals; and the radio-frequency module 1A that transmits radio-frequency signals between the RFIC 3 and an antenna 2.

According to such a configuration, the communication device 5 can achieve the effect of the radio-frequency module 1A.

### 2.2 Example 2

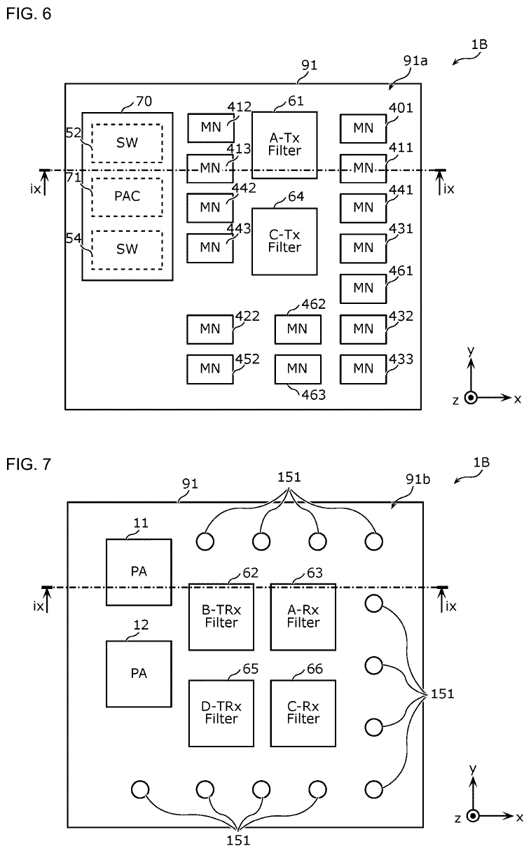

Next, a radio-frequency module 1B, in which the radio-frequency circuit 1 is implemented, is described as Example 2 of the radio-frequency circuit 1 according to the embodiment. Example 2 is different from Example 1 described above mostly in positional relationship between power amplifiers 11 and 12, filters 62 and 65, and an integrated circuit 70. The following description of the radio-frequency module 1B according to Example 2 focuses different points from Example 1 with reference to FIGS. 6 to 9.

### [2.2.1 Component Position of Radio-Frequency Module 1B]

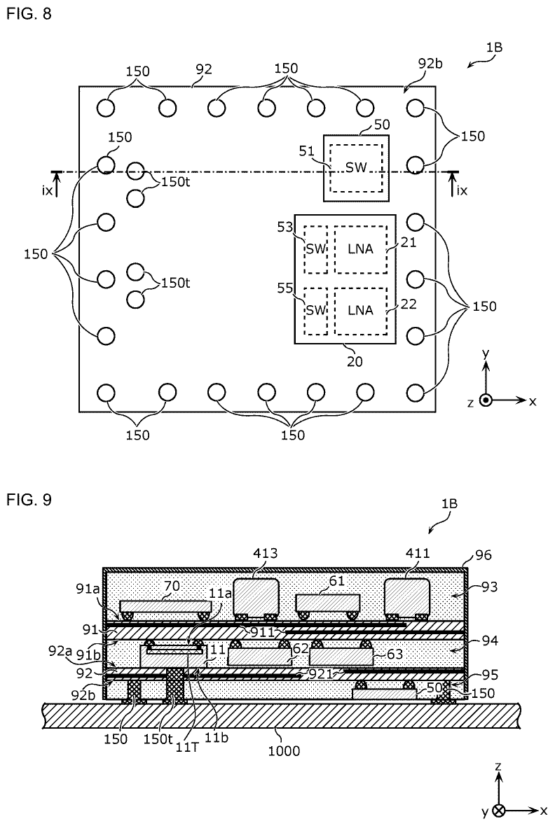

FIG. 6 is a plan view of a major surface 91a of the radio-frequency module 1B according to Example 2. FIG. 7 is a plan view of a major surface 91b of the radio-frequency module 1B according to Example 2. FIG. 7 is a view seen through the major surface 91b side of a module substrate 91 as seen in the positive z-axis direction. FIG. 8 is a plan view of a major surface 92b of the radio-frequency module 1B according to Example 2. FIG. 8 is a view seen through the major surface 92b side of a module substrate 92 as seen in the positive z-axis direction. FIG. 9 is a cross-sectional view of the radio-frequency module 1B according to Example 2. The cross section of the radio-frequency module 1B in FIG. 9 is taken along a line ix-ix of FIGS. 6 to 8.

On the major surface 91a (the upper layer), the integrated circuit 70, matching networks 401, 411 to 413, 422, 431 to 433, 441 to 443, 452, and 461 to 463, and filters 61 and 64 are disposed.

The integrated circuit 70 is an example of a third electronic component including transistors and includes at least one of a PA controller and a switch controller. The integrated circuit 70 includes switches 52 (first switch) and 54 (first switch) and a PA controller 71. The transistors constituting the switches 52 and 54 and the PA controller 71 are formed in a circuit section of the integrated circuit 70. The circuit section can be, for example, the major surface of the integrated circuit 70 facing the module substrate 91. The integrated circuit 70 is disposed on the major surface 91a. The integrated circuit 70 may or may not include switches 52 and 54.

Each of the matching networks 401, 411 to 413, 422, 431 to 433, 441 to 443, 452, and 461 to 463 is composed of a chip inductor, for example. The chip inductors are SMDs each constituting an inductor.

The filters 61 and 64 may be composed of, but not limited to, any one of a SAW filter, a BAW filter, an LC resonance filter, or a dielectric filter, for example.

Between the major surfaces 91b and 92a (the middle layer), the power amplifiers 11 and 12, the filters 62, 63, 65, and 66, and the plural inter-substrate connection terminals 151 are disposed. Between the major surfaces 91b and 92a, a resin member 94 is injected and covers the electronic components disposed between the major surfaces 91b and 92a.

Each of the power amplifiers 11 and 12 includes an amplification transistor and is included in a first electronic component. The amplification transistor of the power amplifier 11 is formed in a circuit section 11T. As illustrated in FIG. 9, the circuit section 11T is formed at a position near the major surface 11a of the major surfaces 11a (fifth major surface) and 11b (sixth major surface) of the power amplifier 11, which are opposite to each other. The power amplifier 11 has the major surface 11a disposed facing the major surface 91b. Similarly, the amplification transistor of the power amplifier 12 is formed in a circuit section 12T. Although not illustrated, the circuit section 12T is formed at a position near the major surface 12a of the major surfaces 12a (fifth major surface) and 12b (sixth major surface) of the power amplifier 12, which are opposite to each other. The power amplifier 12 has the major surface 12a disposed facing the major surface 91b.

The filters 62, 63, 65, and 66 may be composed of, but not limited to, any one of a SAW filter, a BAW filter, an LC resonance filter, or a dielectric filter, for example.

The plural electronic components (the power amplifiers 11 and 12 and the filters 62, 63, 65, and 66), which are disposed between the major surfaces 91b and 92a, are electrically coupled to the module substrate 91 with electrodes interposed therebetween. The electrodes are provided on the side facing the module substrate 91.

In a planar view of the module substrate 91, the power amplifiers 11 and 12 and the integrated circuit 70 at least partially overlap each other. This can shorten control traces connecting the power amplifiers 11 and 12 to the PA controller 71.

On the major surface 92b (the lower layer), integrated circuits 20 and 50, plural external connection terminals 150, and plural heat dissipation conductors 150t are disposed.

The plural heat dissipation conductors 150t overlap the power amplifiers 11 and 12 in a planar view and serve as heat dissipation electrodes of the power amplifiers 11 and 12. More specifically, as illustrated in FIGS. 8 and 9, the plural heat dissipation conductors 150t each have one end joined to the major surface 11b of the power amplifier 11 or the major surface 12b of the power amplifier 12, and extend along a direction (negative z-axis direction) from the major surface 92a to the major surface 92b. The plural heat dissipation conductors 150t each have the other end joined to the motherboard 1000 by at least one of a metal electrode and solder. This can increase the heat dissipation of the power amplifiers 11 and 12. The heat dissipation conductors 150t are composed of, for example, a via conductor having a circular or elliptical cross section parallel to the module substrate 91 and a copper post electrode. However, the shape and material of the heat dissipation conductors 150t are not limited thereto.

The integrated circuit 20 is an example of a second electronic component including at least transistors. The integrated circuit 20 includes low-noise amplifiers 21 and 22 and switches 53 and 55. The circuit elements constituting the low-noise amplifiers 21 and 22 and the switches 53 and 55 are formed on the circuit surface of the integrated circuit 20. The circuit surface can be, for example, the major surface of the integrated circuit 20 facing the module substrate 92. The integrated circuit 20 is disposed on the major surface 92b.

The integrated circuit 50 includes a switch 51. The circuit elements constituting the switch 51 are formed on the circuit surface of a switch device. The circuit surface can be, for example, the major surface of the switch device facing the module substrate 92. The switch 51 may be included in the integrated circuit 20 or 70.

As described above, in the radio-frequency module 1B according to Example 2, the power amplifiers 11 and 12 (first electronic component), the low-noise amplifiers 21 and 22 (second electronic component), and the integrated circuit 70 (third electronic component) are separately disposed on the major surface 91a, between the major surfaces 91b and 92a, and on the major surface 92b.

As described above, in the radio-frequency module 1B according to Example 2, the integrated circuit 70 (third electronic component), the power amplifiers 11 and 12 (first electronic component), and the low-noise amplifiers 21 and 22 (second electronic component) are separately disposed on the major surface 91a, between the major surfaces 91b and 92a, and on the major surface 92b.

### [2.2.2 Effect of Radio-Frequency Module 1B]

As described above, the radio-frequency module 1B according to Example 2 includes: the module substrate 91, which includes the major surfaces 91a and 91b opposite to each other; the module substrate 92, which includes the major surfaces 92a and 92b opposite to each other, the major surface 92a being disposed facing the major surface 91b; the plural electronic components disposed between the major surfaces 91b and 92a, on the major surface 91a, and on the major surface 92b; and the plural external connection terminals 150 disposed on the major surface 92b. The plural electronic components include: the first electronic component including the power amplifiers 11 and/or 12; the second electronic component including the low-noise amplifiers 21 and/or 22; the switches 52 and/or 54 that switch connection and disconnection between the first filter and the power amplifiers 11 and/or 12; and the third electronic component including the PA controller to control the power amplifiers 11 and/or 12 or the switch controller to control the switches 52 and/or 54. The first electronic component is disposed one of between the major surfaces 91b and 92a, on the major surface 91a, and on the major surface 92b. The second electronic component is disposed another one of between the major surfaces 91b and 92a, on the major surface 91a, and on the major surface 92b. The third electronic component is disposed the other one of between the major surfaces 91b and 92a, on the major surface 91a, and on the major surface 92b.

According to such a configuration, the radio-frequency module 1B can be reduced in size and can be inhibited from having poor isolation between the electronic components.

In the radio-frequency module 1B according to Example 2, the first electronic component may be disposed on the major surface 91b and the third electronic component may be disposed on the major surface 91a.

According to such a configuration, the control traces described above can be shortened since the power amplifiers 11 and/or 12 and the power amplifier controller and/or switch controller are disposed opposite to each other with the module substrate 91 interposed therebetween.

In the radio-frequency module 1B according to Example 2, for example, the power amplifier 11 includes the major surfaces 11a and 11b opposite to each other, and the circuit section 11T that is formed at a position closer to the major surface 11a than the major surface 11b and includes the amplification transistor. The power amplifier 11 may have the major surface 11a disposed facing the major surface 91b. The heat dissipation conductor 150t extending along the direction from the major surface 92a to the major surface 92b may be joined to the major surface 11b.

According to such a configuration, the heat dissipation of the power amplifier 11 can be increased.

In the radio-frequency module 1B according to Example 2, for example, the second electronic component may be disposed on the major surface 92b.

A communication device 5 according to Example 2 includes: an RFIC 3 that processes radio-frequency signals; and the radio-frequency module 1B that transmits radio-frequency signals between the RFIC 3 and an antenna 2.

According to such a configuration, the communication device 5 can achieve the effect of the radio-frequency module 1B.

### 2.3 Example 3

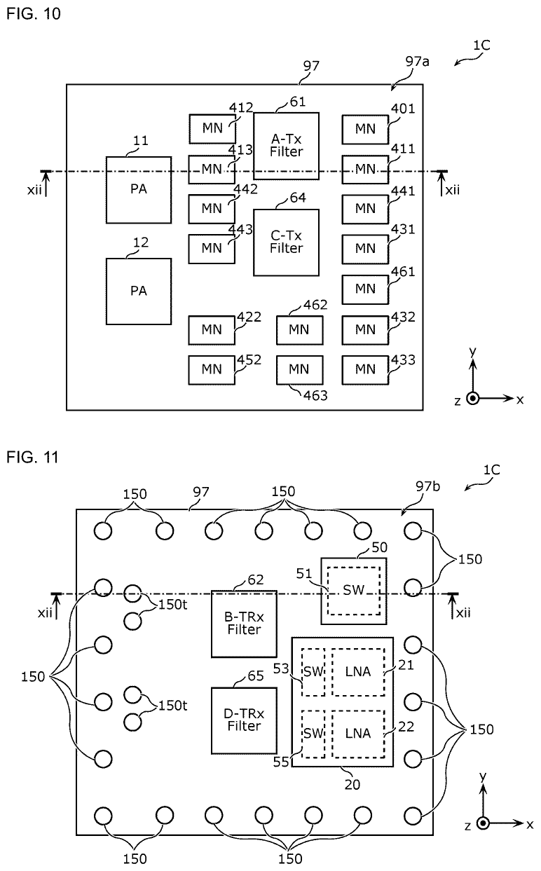

Next, a radio-frequency module 1C, in which the radio-frequency circuit 1 is implemented, is described as Example 3 of the radio-frequency circuit 1 according to the embodiment. Example 3 is different from Examples 1 and 2 described above mostly in being composed of a single module substrate. The following description of the radio-frequency module 1C according to Example 3 focuses different points from Example 1 with reference to FIGS. 10 to 13.

### [2.3.1 Component Position of Radio-Frequency Module 1B]

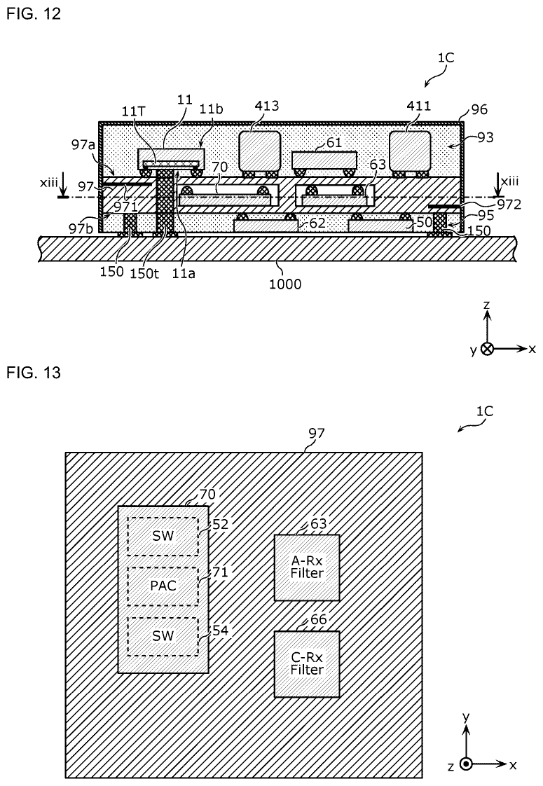

FIG. 10 is a plan view of a major surface 97a of the radio-frequency module 1C according to Example 3. FIG. 11 is a plan view of a major surface 97b of the radio-frequency module 1C according to Example 3. FIG. 11 is a view seen through the major surface 97b side of a module substrate 97 as seen in the positive z-axis direction. FIG. 12 is a cross-sectional view of the radio-frequency module 1C according to Example 3. The cross section of the radio-frequency module 1C in FIG. 12 is taken along a line xii-xii of FIGS. 10 and 11. FIG. 13 is a cross-sectional view of the radio-frequency module 1C according to Example 3. The cross section of the radio-frequency module 1C in FIG. 13 is taken along a line xiii-xiii of FIG. 12.

Similarly to FIGS. 2 to 5, FIGS. 10 to 13 do not illustrate traces connecting plural electronic components disposed in the module substrates 97. FIGS. 10 and 11 do not illustrate the resin members 93 and 95, which cover plural electronic components, and the shield electrode layer 96, which covers the surfaces of the resin members 93 and 95.

In addition to the plural electronic components including the plural circuit elements illustrated in FIG. 1, the radio-frequency module 1C includes the module substrate 97, resin members 93 and 95, shield electrode layer 96, plural heat dissipation conductors 150t, and plural external connection terminals 150.

The module substrate 97 includes the major surfaces 97a and 97b, which are opposite to each other. The major surfaces 97a and 97b are examples of the first and second major surfaces, respectively. The module substrate 97 can be, but not limited to, an LTCC substrate, an HTCC substrate, an embedded printed circuit board, a substrate including an RDL, a printed circuit board, or the like, for example.

Inside the module substrate 97, ground conductors 971 and 972 may be formed in a direction parallel to the major surfaces 97a and 97b. This enhances the isolation between the electronic components disposed on the major surface 97a and the electronic components disposed on the major surface 97b.

On the major surface 97a (the upper layer), power amplifiers 11 and 12, matching networks 401, 411 to 413, 422, 431 to 433, 441 to 443, 452, and 461 to 463, and filters 61 and 64 are disposed.

Each of the power amplifiers 11 and 12 includes an amplification transistor and is included in a first electronic component. The amplification transistor of the power amplifier 11 is formed in a circuit section 11T. As illustrated in FIG. 12, the circuit section 11T is formed at a position near the major surface 11a of the major surfaces 11a (third major surface) and 11b (fourth major surface) of the power amplifier 11, which are opposite to each other. The power amplifier 11 has the major surface 11a disposed facing the major surface 97a. Similarly, the amplification transistor of the power amplifier 12 is formed in a circuit section 12T. Although not illustrated, the circuit section 12T is formed at a position near the major surface 12a of the major surfaces 12a (third major surface) and 12b (fourth major surface) of the power amplifier 12, which are opposite to each other. The power amplifier 12 has the major surface 12a disposed facing the major surface 97a.

Each of the matching networks 401, 411 to 413, 422, 431 to 433, 441 to 443, 452, and 461 to 463 is composed of a chip inductor, for example. The chip inductors are SMDs each constituting an inductor. The chip inductors are disposed on the major surface 97a. Each matching network may include a chip inductor and/or a chip capacitor, and the positions of the chip capacitors are not limited. All the matching networks are not necessarily surface-mounted. For example, an inductor and/or a capacitor included in any matching network may be formed within the module substrate 97.

The filters 61 and 64 may be composed of, but not limited to, any one of a SAW filter, a BAW filter, an LC resonance filter, or a dielectric filter, for example.

The resin member 93 covers the major surface 97a and the electronic components on the major surface 97a. The resin member 93 has a function of enhancing the reliability, including mechanical strength and moisture resistance, of the electronic components on the major surface 97a. The resin member 93 may or may not be included in the radio-frequency module 1C.

Within the module substrate 97 (the middle layer), an integrated circuit 70, filters 63 and 66, and plural heat dissipation conductors 150t are disposed.

The integrated circuit 70 is an example of a third electronic component including transistors and includes at least one of a PA controller and a switch controller. The integrated circuit 70 includes switches 52 (first switch) and 54 (first switch) and the PA controller 71. The integrated circuit 70 may or may not include the switches 52 and 54.

The filters 63 and 66 may be composed of, but not limited to, any one of a SAW filter, a BAW filter, an LC resonance filter, or a dielectric filter, for example.

The plural heat dissipation conductors 150t overlap the power amplifiers 11 and 12 in a planar view and serve as heat dissipation electrodes of the power amplifiers 11 and 12. More specifically, as illustrated in FIGS. 11 and 12, the plural heat dissipation conductors 150t each have one end joined to the major surface 11a of the power amplifier 11 or the major surface 12a of the power amplifier 12, and extend along a direction (negative z-axis direction) from the major surface 97a to the major surface 97b. The plural heat dissipation conductors 150t each have the other end joined to the motherboard 1000 by at least one of a metal electrode and solder. This can increase the heat dissipation of the power amplifiers 11 and 12. The heat dissipation conductors 150t are composed of, for example, a via conductor having a circular or elliptical cross section parallel to the module substrate 97 and a copper post electrode. However, the shape and material of the heat dissipation conductors 150t are not limited thereto.

In a planar view of the module substrate 97, the power amplifiers 11 and 12 and the integrated circuit 70 at least partially overlap each other. This can shorten control traces connecting the power amplifiers 11 and 12 to the PA controller 71.

On the major surface 97b (the lower layer), filters 62 and 65, integrated circuits 20 and 50, the plural external connection terminals 150, and the plural heat dissipation conductors 150t are disposed.

The filters 62 and 65 may be composed of, but not limited to, any one of a SAW filter, a BAW filter, an LC resonance filter, or a dielectric filter, for example.

The integrated circuit 20 is an example of a second electronic component including at least transistors. The integrated circuit 20 includes the low-noise amplifiers 21 and 22 and switches 53 and 55. The circuit elements constituting the low-noise amplifiers 21 and 22 and the switches 53 and 55 are formed on the circuit surface of the integrated circuit 20. The integrated circuit 20 is disposed on the major surface 97b.

The integrated circuit 50 includes a switch 51. The switch 51 may be included in the integrated circuit 20 or 70.

The plural external connection terminals 150 include the antenna connection terminal 100, radio-frequency input terminals 111 and 112, radio-frequency output terminals 121 and 122, and control terminal 131, which are illustrated in FIG. 1, and further include ground terminals. The plural external connection terminals 150 are individually joined to input-output terminals, a ground terminal, and/or other terminals on the motherboard 1000, which is laid in the negative z-axis direction with respect to the radio-frequency module 1C.

The resin member 95 covers the major surface 97b and the electronic components on the major surface 97b. The resin member 95 has a function of enhancing the reliability, including mechanical strength and moisture resistance, of the electronic components on the major surface 97b. The resin member 95 may or may not be included in the radio-frequency module 1C.

As described above, in the radio-frequency module 1C according to Example 3, the power amplifiers 11 and 12 (first electronic component), the integrated circuit 70 (third electronic component), and the low-noise amplifiers 21 and 22 (second electronic component) are separately disposed on the major surface 97a, within the module substrate 97, and on the major surface 97b.

In the radio-frequency module 1C according to Example 3, the first electronic component may be disposed one of (i) on the major surface 97a, (ii) within the module substrate 97, and (iii) on the major surface 97b. The second electronic component may be disposed another one of (i) to (iii) where the first electronic component is not disposed. The third electronic component may be disposed the other one of (i) to (iii) where the first and second electronic components are not disposed.

In the radio-frequency module 1C according to Example 3, for example, the power amplifiers 11 and 12 (first electronic component) may be disposed within the module substrate 97, the integrated circuit 70 (third electronic component) may be disposed on the major surface 97a, and the low-noise amplifiers 21 and 22 (second electronic component) may be disposed on the major surface 97b.

In this case, the amplification transistor of the power amplifier 11 is formed in the circuit section 11T. The circuit section 11T is formed at a position near the major surface 11a of the major surfaces 11a (third major surface) and 11b (fourth major surface) of the power amplifier 11, which are opposite to each other. The power amplifier 11 has the major surface 11a disposed facing the major surface 97a than the major surface 11b. Similarly, the amplification transistor of the power amplifier 12 is formed in the circuit section 12T. The circuit section 12T is formed at a position near the major surface 12a of the major surfaces 12a (third major surface) and 12b (fourth major surface) of the power amplifier 12, which are opposite to each other. The power amplifier 12 has the major surface 12a disposed closer to the major surface 97a than the major surface 12b.

### [2.3.2 Effect of Radio-Frequency Module 1C]

As described above, the radio-frequency module 1C according to Example 3 includes: the module substrate 97, which includes the major surfaces 97a and 97b opposite to each other; the plural electronic components disposed on the major surface 97a, on the major surface 97b, and within the module substrate 97; and the plural external connection terminals 150 disposed on the major surface 97b. The plural electronic components include: the first electronic component including the power amplifiers 11 and/or 12; the second electronic component including the low-noise amplifiers 21 and/or 22; the switches 52 and/or 54 that switch connection and disconnection between the first filter and the power amplifiers 11 and/or 12; and the third electronic component including the PA controller to control the power amplifiers 11 and/or 12 or the switch controller to control the switches 52 and/or 54. The first electronic component is disposed one of on the major surface 97a, on the major surface 97b, and within the module substrate 97. The second electronic component is disposed another one of on the major surface 97a, on the major surface 97b, and within the module substrate 97. The third electronic component is disposed the other one of on the major surface 97a, on the major surface 97b, and within the module substrate 97.

According to such a configuration, the plural electronic components are disposed in three layers, including on the major surface 97a, on the major surface 97b, and within the module substrate 97. This can implement reduction in area of the radio-frequency module 1C in a planar view, that is, reduction in size of the radio-frequency module 1C. Since the power amplifiers 11 and/or 12 and the power amplifier controller and/or the switch controller are disposed in different layers, digital control signals inputted and outputted to and from the power amplifier controller and/or the switch controller, for example, can be inhibited from entering the power amplifiers 11 and/or 12 as digital noise. Since the low-noise amplifiers 21 and/or 22 and the power amplifier controller and/or the switch controller are disposed in different layers, control signals inputted and outputted to and from the power amplifier/switch controller, for example, can be inhibited from entering the low-noise amplifiers 21 and/or 22 as noise. Since the power amplifiers 11 and/or 12 and the low-noise amplifiers 21 and/or 22 are disposed in different layers, transmission signals and harmonics thereof outputted from the power amplifiers 11 and/or 12, for example, can be inhibited from entering the low-noise amplifiers 21 and/or 22 as noise. Therefore, the radio-frequency module can be reduced in size and can be inhibited from having poor isolation between the electronic components.

In the radio-frequency module 1C according to Example 3, for example, the first electronic component and the third electronic component may at least partially overlap each other in a planar view of the module substrate 97.

According to such a configuration, control traces connecting the power amplifiers 11 and/or 12 to the power amplifier controller and/or switch controller can be shortened, thus reducing noise generated from the control traces.

In the radio-frequency module 1C according to Example 3, for example, the first electronic component may be disposed on the major surface 97a and the third electronic component may be disposed inside the module substrate 97.

According to such a configuration, the control traces can be shortened since the power amplifiers 11 and/or 12 and the power amplifier controller and/or switch controller are disposed in different layers.

In the radio-frequency module 1C according to Example 3, for example, the power amplifier 11 includes the major surfaces 11a and 11b opposite to each other, and the circuit section 11T that is formed at a position closer to the major surface 11a than the major surface 11b and includes the amplification transistor. The power amplifier 11 may have the major surface 11a disposed facing the major surface 97a. The heat dissipation conductor 150t extending along the direction from the major surface 97a to the major surface 97b is joined to the major surface 11a.

According to such a configuration, the heat dissipation of the power amplifier 11 can be increased.

In the radio-frequency module 1C according to Example 3, for example, the first electronic component may be disposed inside the module substrate 97, and the third electronic component may be disposed on the major surface 97a.

According to such a configuration, the control traces can be shortened since the power amplifiers 11 and/or 12 and the power amplifier controller and/or switch controller are disposed in different layers.

In the radio-frequency module 1C according to Example 3, for example, the power amplifier 11 includes the major surfaces 11a and 11b opposite to each other, and the circuit section 11T that is formed at a position closer to the major surface 11a than the major surface 11b and includes the amplification transistor. The power amplifier 11 has the major surface 11a disposed closer to the major surface 97a than the major surface 11b. The heat dissipation conductor 150t extending along the direction from the major surface 97a to the major surface 97b is joined to the major surface 11b.

According to such a configuration, the heat dissipation of the power amplifier 11 can be increased.

In the radio-frequency module 1C according to Example 3, for example, the second electronic component may be disposed on the major surface 97b.

A communication device 5 according to Example 3 includes: an RFIC 3 that processes radio-frequency signals; and the radio-frequency module 1C that transmits radio-frequency signals between the RFIC 3 and an antenna 2.

According to such a configuration, the communication device 5 can achieve the effect of the radio-frequency module 1C.

### (Modification)

The radio-frequency module and communication device according to the present disclosure are described based on the embodiment and examples hereinabove but are not limited to the aforementioned embodiment and examples. The present disclosure includes another example implemented by a combination of any constituent elements of the aforementioned examples, modifications obtained by performing for the aforementioned embodiment and examples, various changes that can be conceived by those skilled in the art without departing from the spirit of the present disclosure, and various devices incorporating the aforementioned radio-frequency module.

In the circuit configurations of the radio-frequency circuit and communication device according to the aforementioned embodiments, for example, other circuit elements, traces, and the like may be inserted in paths connecting circuit elements and signal paths disclosed in the drawings. For example, a matching network may be inserted between the switch 51 and the filter 62 and/or between the switch 51 and the filter 65.

The positions of the plural electronic components are illustrated in the aforementioned examples by way of example and are not limited to the aforementioned examples. For example, the position of any electronic component in any of the aforementioned examples may be substituted with the position of the same electronic component in the other example.

The plural external connection terminals 150 are composed of copper post electrodes in the aforementioned examples but are not limited thereto. For example, the plural external connection terminals 150 may be bump electrodes. In this case, the radio-frequency module may or may not include the resin member 95.

### INDUSTRIAL APPLICABILITY

The present disclosure can be widely used in communication devices, including mobile phones, as a radio-frequency module provided in the front end.

### REFERENCE SIGNS LIST

1 RADIO-FREQUENCY CIRCUIT
1A, 1B, 1C RADIO-FREQUENCY MODULE
2 ANTENNA
3 RFIC
4 BBIC
5 COMMUNICATION DEVICE
11, 12 POWER AMPLIFIER
11a, 11b, 12a, 12b, 91a, 91b, 92a, 92b, 97a, 97b MAJOR SURFACE
11T, 12T CIRCUIT SECTION
20, 50, 70 INTEGRATED CIRCUIT
21, 22 LOW-NOISE AMPLIFIER
51, 52, 53, 54, 55 SWITCH
61, 62, 63, 64, 65, 66 FILTER
71 PA CONTROLLER
91, 92, 97 MODULE SUBSTRATE
93, 94, 95 RESIN MEMBER
96 SHIELD ELECTRODE LAYER
100 ANTENNA CONNECTION TERMINAL
111, 112 RADIO-FREQUENCY INPUT TERMINAL
121, 122 RADIO-FREQUENCY OUTPUT TERMINAL
131 CONTROL TERMINAL
150 EXTERNAL CONNECTION TERMINAL
150t HEAT DISSIPATION CONDUCTOR
151 INTER-SUBSTRATE CONNECTION TERMINAL
401, 411, 412, 413, 422, 431, 432, 433, 441, 442, 443, 452, 461, 462, 463 MATCHING NETWORK
511, 512, 513, 514, 515, 516, 517, 521, 522, 523, 524, 531, 532, 533, 541, 542, 543, 544, 551, 552, 553 TERMINAL
911, 921, 971, 972 GROUND CONDUCTOR
1000 MOTHERBOARD

1. A radio-frequency module, comprising:
a first module substrate including a first major surface and a second major surface that are opposite to each other;
a second module substrate including a third major surface and a fourth major surface that are opposite to each other, the third major surface being disposed facing the second major surface;
a plurality of electronic components disposed between the second major surface and the third major surface, on the first major surface, and on the fourth major surface; and
a plurality of external connection terminals disposed on the fourth major surface, wherein
the plurality of electronic components include
a first electronic component including a power amplifier,
a second electronic component including a low-noise amplifier,
a first switch that switches connection and disconnection between a first filter and the power amplifier, and
a third electronic component including a PA controller to control the power amplifier or a switch controller to control the first switch,
the first electronic component is disposed one of between the second major surface and the third major surface, on the first major surface, and on the fourth major surface,
the second electronic component is disposed another one of between the second major surface and the third major surface, on the first major surface, and on the fourth major surface, and
the third electronic component is disposed other one of between the second major surface and the third major surface, on the first major surface, and on the fourth major surface.

2. The radio-frequency module according to claim 1, wherein
the first electronic component and the third electronic component at least partially overlap each other in a planar view of the first module substrate or the second module substrate.

3. The radio-frequency module according to claim 2, wherein
the first electronic component is disposed on the first major surface, and
the third electronic component is disposed on the second major surface.

4. The radio-frequency module according to claim 3, wherein
the power amplifier includes
a fifth major surface and a sixth major surface that are opposite to each other, and
a circuit section that is formed at a position closer to the fifth major surface than the sixth major surface and includes an amplification transistor,
the power amplifier has the fifth major surface disposed facing the first major surface, and
a heat dissipation conductor extending along a direction from the first major surface to the fourth major surface is joined to the fifth major surface.

5. The radio-frequency module according to claim 2, wherein
the first electronic component is disposed on the second major surface, and
the third electronic component is disposed on the first major surface.

6. The radio-frequency module according to claim 5, wherein
the power amplifier includes
a fifth major surface and a sixth major surface that are opposite to each other, and
a circuit section that is formed at a position closer to the fifth major surface than the sixth major surface and includes an amplification transistor,
the power amplifier has the fifth major surface disposed facing the second major surface, and
a heat dissipation conductor extending along a direction from the third major surface to the fourth major surface is joined to the sixth major surface.

7. The radio-frequency module according to claim 6, wherein
the second electronic component is disposed on the fourth major surface.

8. A radio-frequency module, comprising:
a module substrate including a first major surface and a second major surface that are opposite to each other;
a plurality of electronic components disposed on the first major surface, on the second major surface, and within the module substrate; and
a plurality of external connection terminals disposed on the second major surface, wherein
the plurality of electronic components include
a first electronic component including a power amplifier,
a second electronic component including a low-noise amplifier,
a first switch that switches connection and disconnection between a first filter and the power amplifier, and
a third electronic component including a PA controller to control the power amplifier or a switch controller to control the first switch,
the first electronic component is disposed one of on the first major surface, on the second major surface, and within the module substrate,
the second electronic component is disposed another one of on the first major surface, on the second major surface, and within the module substrate, and
the third electronic component is disposed other one of on the first major surface, on the second major surface, and within the module substrate.

9. The radio-frequency module according to claim 8, wherein
the first electronic component and the third electronic component at least partially overlap each other in a planar view of the module substrate.

10. The radio-frequency module according to claim 9, wherein
the first electronic component is disposed on the first major surface, and
the third electronic component is disposed inside the module substrate.

11. The radio-frequency module according to claim 10, wherein
the power amplifier includes a third major surface and a fourth major surface that are opposite to each other, and
a circuit section that is formed at a position closer to the third major surface than the fourth major surface and includes an amplification transistor,
the power amplifier has the third major surface disposed facing the first major surface, and
a heat dissipation conductor extending along a direction from the first major surface to the second major surface is joined to the third major surface.

12. The radio-frequency module according to claim 9, wherein
the first electronic component is disposed inside the module substrate, and
the third electronic component is disposed on the first major surface.

13. The radio-frequency module according to claim 12, wherein
the power amplifier includes
a third major surface and a fourth major surface that are opposite to each other, and
a circuit section that is formed at a position closer to the third major surface than the fourth major surface and includes an amplification transistor,
the power amplifier has the third major surface disposed closer to the first major surface than the fourth major surface, and
a heat dissipation conductor extending along a direction from the first major surface to the second major surface is joined to the fourth major surface.

14. The radio-frequency module according to claim 13, wherein
the second electronic component is disposed on the second major surface.

15. The radio-frequency module according to claim 14, wherein
The third electronic component is included in a semiconductor IC.

16. A communication device comprising:
a signal processing circuit that processes radio-frequency signals; and
the radio-frequency module according to claim 1 that transmits the radio-frequency signals between the signal processing circuit and an antenna.

17. The radio-frequency module according to claim 1, wherein
the first electronic component is disposed on the first major surface, and
the third electronic component is disposed on the second major surface.

18. The radio-frequency module according to claim 1, wherein
the first electronic component is disposed on the second major surface, and
the third electronic component is disposed on the first major surface.

19. The radio-frequency module according to claim 8, wherein
the first electronic component is disposed on the first major surface, and
the third electronic component is disposed inside the module substrate.

20. The radio-frequency module according to claim 8, wherein
the first electronic component is disposed inside the module substrate, and
the third electronic component is disposed on the first major surface.
